(19) United States
(12) Patent Application Publication
(10) Pub. No.: US 2024/0422902 A1
(43) Pub. Date: Dec. 19, 2024

(54) DIELECTRIC SHEET, SUBSTRATE FOR HIGH FREQUENCY PRINTED WIRING BOARD, AND HIGH FREQUENCY PRINTED WIRING BOARD

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Shingo KAIMORI, Osaka (JP); Takashi NINOMIYA, Osaka (JP); Yoshio MEZAKI, Osaka (JP); Motohiko SUGIURA, Osaka (JP); Eiko IMAZAKI, Osaka (JP); Yasuhiro OKUDA, Osaka (JP)

(73) Assignees: SUMITOMO ELECTRIC INDUSTRIES, LTD., Osaka (JP); SUMITOMO ELECTRIC PRINTED CIRCUITS, INC., Shiga (JP)

(21) Appl. No.: 18/703,347

(22) PCT Filed: Oct. 31, 2022
(86) PCT No.: PCT/JP2022/040724

§ 371 Date: Apr. 21, 2024

(30) Foreign Application Priority Data
Nov. 8, 2021 (JP) 2021-182130

(51) Int. Cl. H05K 1/03; C08K 9/06; C08L 27/18; H05K 1/02

(52) U.S. Cl. CPC H05K 1/036; C08K 9/06; C08L 27/18; H05K 1/024; C08K 2201/003; C08L 2203/20

(57) ABSTRACT

A dielectric sheet includes a polytetrafluoroethylene and spherical inorganic fillers, wherein a mass ratio of the inorganic fillers to the polytetrafluoroethylene is 1.3 or more, the inorganic fillers have an average particle diameter of 0.3 μm to 4.0 μm, and the inorganic fillers include a silica filler. Part of the polytetrafluoroethylene is present in the form of a plurality of fibrous bodies, and in a SEM image of a surface of the dielectric sheet after a 180-degree peel test, at least part of fibrous bodies among the plurality of fibrous bodies has areas with a thickness of 0.1 μm to 3.0 μm and a length of 50 μm to 5000 μm, and an average space between the areas of the at least part of fibrous bodies is 10 μm or less.

### TECHNICAL FIELD

The present disclosure relates to a dielectric sheet, a substrate for a high frequency printed wiring board, and a high frequency printed wiring board. The present application claims priority to Japanese Patent Application No. 2021-182130, which is a Japanese Patent Application filed on Nov. 8, 2021. The content disclosed in that Japanese Patent Application is incorporated herein by reference in its entirety.

### BACKGROUND ART

Recently, with reduction in size and weight of electronic devices, there has been also increasing needs for reduction in size of high frequency printed wiring boards used for the electronic devices. In light of this, a polyimide film, which is excellent in insulation, flexibility, heat resistance, and others, and can be in the form of a thinner film, is employed these days as a base film for the high frequency printed wiring boards (see Japanese Patent Laying-Open No. 2008-235346).

On the other hand, the amounts of information and telecommunications just keep growing, and in order to support this, telecommunications in a high frequency range, including microwaves and millimeter waves, is actively used for devices such as IC cards and mobile communication terminals. Accordingly, there is a need for high frequency printed wiring boards that have small transmission loss when used in a high frequency range.

### CITATION LIST

### Patent Literature

PTL 1: Japanese Patent Laying-Open No. 2008-235346

### SUMMARY OF INVENTION

A dielectric sheet according to one aspect of the present disclosure comprises a polytetrafluoroethylene and spherical inorganic fillers, wherein a mass ratio of the inorganic fillers to the polytetrafluoroethylene is 1.3 or more; the inorganic fillers have an average particle diameter of 0.3 μm or more and 4.0 μm or less; the inorganic fillers comprise a silica filler; part of the polytetrafluoroethylene is present in the form of a plurality of fibrous bodies; and in a SEM image of a surface of the dielectric sheet after a 180-degree peel test, at least part of fibrous bodies among the plurality of fibrous bodies has areas with a thickness of 0.1 μm or more and 3.0 μm or less and a length of 50 μm or more and 5000 μm or less, and an average space between the areas of the at least part of fibrous bodies is 10 μm or less.

### BRIEF DESCRIPTION OF DRAWINGS

FIG. 1 is a schematic cross-sectional view of the dielectric sheet according to one embodiment of the present disclosure.

FIG. 2 is a view showing a step (the first rolling) in manufacture of the dielectric sheet according to one embodiment of the present disclosure.

FIG. 3 is a view showing a sub-step in a step (the repeating of the rolling) in manufacture of the dielectric sheet according to one embodiment of the present disclosure.

FIG. 4 is a view showing another sub-step in a step (the repeating of the rolling) in manufacture of the dielectric sheet according to one embodiment of the present disclosure.

FIG. 5 is a view showing still another sub-step in a step (the repeating of the rolling) in manufacture of the dielectric sheet according to one embodiment of the present disclosure.

FIG. 6 is a view showing yet another sub-step in a step (the repeating of the rolling) in manufacture of the dielectric sheet according to one embodiment of the present disclosure.

FIG. 7 is a schematic cross-sectional view of a substrate for a high frequency printed wiring board according to one embodiment of the present disclosure.

FIG. 8 is a SEM image of the surface of the dielectric sheet of test No. 1 after a peel test.

FIG. 9 is a SEM image of the surface of the dielectric sheet of test No. 2 after the peel test.

FIG. 10 is a SEM image of the surface of the dielectric sheet of test No. 3 after the peel test.

FIG. 11 is a SEM image of the surface of the dielectric sheet of test No. 4 after the peel test.

FIG. 12 is a SEM image of the surface of the dielectric sheet of test No. 5 after the peel test.

FIG. 13 is a SEM image of the surface of the dielectric sheet of test No. 6 after the peel test.

FIG. 14 is a SEM image of the surface of the dielectric sheet of test No. 7 after the peel test.

FIG. 15 is a SEM image showing burrs generated in the copper foils in test No. 5 in the evaluation test for workability.

FIG. 16 is a SEM image showing burrs generated in the copper foils in test No. 7 in the evaluation test for workability.

FIG. 17 is an imagery view for illustrating an adjacent rotated line segment of an approximate line segment and the adjacent distance between approximate line segments.

FIG. 18 is another imagery view for illustrating an adjacent rotated line segment of an approximate line segment and the adjacent distance between approximate line segments.

### DETAILED DESCRIPTION

### Problem to be Solved by the Present Disclosure

As an insulation base material of substrates for high frequency printed wiring boards, a dielectric sheet including a polytetrafluoroethylene as a main component is known. Since a polytetrafluoroethylene has a small dielectric constant, the dielectric sheet including a polytetrafluoroethylene as a main component is suitable for an insulation base material of substrates for high frequency printed wiring boards for high frequency signal processing. A film of such a single fluororesin can be obtained by, for example, extrusion molding the resin into the form of a tape and rolling the resulting tape into a thin film sheet.

For ensuring favorable characteristics in high frequencies of high frequency printed wiring boards and also ensuring the reliability of electrical connection of interlayer connecting holes, it is needed that a dielectric sheet shows a small change in its dimensions according to temperature changes. Polytetrafluoroethylenes show a large percent change in its dimensions according to temperature changes. Then, a silica filler is added to the polytetrafluoroethylene to thereby improve dimension stability of a dielectric sheet against temperature changes. As the silica filler, generally used is a pulverized type large silica filler having an average particle diameter of more than 10 μm. The present inventors have however found that a dielectric sheet including such silica filler has a large roughness of inner walls of electrically connecting holes, such as through holes, or has burrs on the holes, thereby resulting in the poor reliability of electrical connection, and also found that when holes are made in the dielectric sheet using a drill, the drill is worn down very fast to easily result in a need for replacement of the drill in short time.

The present disclosure has been made under the above-described circumstances, and an object thereof is to provide a dielectric sheet excellent in characteristics in high frequencies, workability, and peel strength.

### Advantageous Effect of the Present Disclosure

The dielectric sheet of the present disclosure is excellent in characteristics in high frequencies, workability, and peel strength.

### Description of Embodiments

First, embodiments of the present disclosure are listed and described.
[1] A dielectric sheet according to one aspect of the present disclosure comprises a polytetrafluoroethylene and spherical inorganic fillers, wherein a mass ratio of the inorganic fillers to the polytetrafluoroethylene is 1.3 or more; the inorganic fillers have an average particle diameter of 0.3 μm or more and 4.0 μm or less; the inorganic fillers comprise a silica filler; part of the polytetrafluoroethylene is present in the form of a plurality of fibrous bodies; and in a SEM image of a surface of the dielectric sheet after a 180-degree peel test, at least part of fibrous bodies among the plurality of fibrous bodies has areas with a thickness of 0.1 μm or more and 3.0 μm or less and a length of 50 μm or more and 5000 μm or less, and an average space between the areas of the at least part of fibrous bodies is 10 μm or less.

As described above, a fluororesin such as a polytetrafluoroethylene is excellent in characteristics in high frequencies but has a large coefficient of linear expansion and therefore a large percent change in its dimensions according to a temperature change. Since a high frequency has a short wavelength, a change of a circuit in its dimensions exerts a large influence on electric characteristics of the circuit so that the characteristics of the circuit in high frequencies may be impaired. In addition, for example, in an environment with large temperature changes, such as a heat cycle test, change in the dimension in the thickness direction may cause a crack in a conductive plating on the inner wall of an interlayer connecting hole so that reliability of electrical connection may be impaired. Then, a silica filler is used to improve the dimension stability of a dielectric sheet of polytetrafluoroethylene against temperature changes. As the silica filler generally used, a pulverized type silica filler having an average particle diameter of more than 10 μm is used most widely. However, a dielectric sheet including such silica filler tends to have poor workability. The present inventors have found that when a spherical silica filler having a small average particle diameter is employed for a dielectric sheet, the workability is improved, but further have found that when the dielectric sheet including the silica filler having a small average particle diameter is allowed to adhere to copper foil, the copper foil has a decreased peel strength.

The dielectric sheet includes a polytetrafluoroethylene and spherical inorganic fillers, and accordingly, has a small dielectric constant and favorable workability in, for example, boring holes. Due to a mass ratio of the inorganic fillers to the polytetrafluoroethylene of 1.3 or more, the dielectric sheet has a decreased coefficient of linear expansion, and therefore improved dimension stability against temperature change, and accordingly, the dielectric sheet is excellent in the characteristics in high frequencies. In addition, due to an average particle diameter of the inorganic fillers of 0.3 μm or more and 4.0 μm or less, the dielectric sheet is excellent in coefficient of linear expansion and workability. Furthermore, the silica filler included in the inorganic fillers has a small dielectric constant and is inexpensive, and a spherical silica filler is easily manufactured; accordingly, the dielectric sheet has a decreased dielectric constant and is inexpensive. In the dielectric sheet, part of the polytetrafluoroethylene is present in the form of a plurality of fibrous bodies, and the fibrous bodies are formed so as to have oriented components in the thickness direction of the dielectric sheet. In a 180-degree peel test of a test sample composed of the dielectric sheet and an adhered allowed to strongly adhere to each other, the fibrous bodies act to resist against the peeling force applied mainly in the thickness direction because of entanglement of the fibrous bodies with each other and the adhesiveness of the fibrous bodies to the inorganic fillers, to thereby obtain a large peel strength. In the 180-degree peel test, the fibrous bodies are extended and oriented in one direction along the peeling surface (the direction in which the test sample is pulled). Furthermore, in a SEM image of a surface of the dielectric sheet after a 180-degree peel test, at least part of fibrous bodies among the plurality of fibrous bodies has areas with a thickness of 0.1 μm or more and 3.0 μm or less and a length of 50 μm or more and 5000 μm or less, and an average space between the areas of the at least part of fibrous bodies is 10 μm or less, whereby the peel strength in the thickness direction of the dielectric sheet can be improved. The “SEM (Scanning Electron Microscope) image” means an image obtained through observation under a scanning electron microscope. The “at least part of fibrous bodies” means two or more fibrous bodies.
[2] In [1], the peel strength in the 180-degree peel test is preferably 10 N/cm or more. When the peel strength in the 180-degree peel test is 10 N/cm or more, the dielectric sheet has improved durability.
[3] In [1] or [2], the content of the silica filler in the inorganic fillers is preferably 70 mass % or more and 100 mass % or less. When the content of the silica filler in the inorganic fillers is 70 mass % or more and 100 mass % or less, the dielectric sheet can have a more decreased coefficient of linear expansion and therefore more improved dimension stability, thereby resulting in improved characteristics in high frequencies.
[4] In any of [1] to [3], the silica filler preferably has, on the surface thereof, a hydrocarbon group having 4 or more carbon atoms. When the silica filler has, on the surface thereof, a hydrocarbon group having 4 or more carbon atoms, the silica filler can have a higher hydrophobicity and therefore a decreased water absorption percentage so that the dielectric constant and the dielectric loss tangent of the dielectric sheet can be kept small.
[5] A substrate for a high frequency printed wiring board according to another aspect of the present disclosure comprises the dielectric sheet according to [1] to [4] as described above, and copper foil directly or indirectly laid on the surface of the dielectric sheet. Since the substrate for a high frequency printed wiring board includes the dielectric sheet and copper foil directly or indirectly laid on the surface of the dielectric sheet, the substrate is excellent in the characteristics in high frequencies and the peel strength and can have improved durability.
[6] A high frequency printed wiring board according to still another aspect of the present disclosure comprises the substrate for a high frequency printed wiring board according to [5] as described above. Since the high frequency printed wiring board includes the substrate for a high frequency printed wiring board, the high frequency printed wiring board is excellent in the characteristics in high frequencies and the peel strength and can have improved durability.

In the present disclosure, the “average particle diameter” of the silica filler means the particle diameter of the primary particle represented by the median diameter D50 in the particle size distribution. The average particle diameter can be measured using a particle size distribution analyzer (for example, “MT3300II” manufactured by MicrotracBEL Corp.). The “coefficient of linear expansion” means the coefficient of thermal expansion of the dielectric sheet in the thickness direction, the coefficient being a value calculated from found values from 20° C. to 120° C. by a measurement system using laser interferometry. For the observation in the process of measuring the “thickness of the fibrous body,” the “length of the area of the fibrous body,” and the “average space between the areas of the fibrous bodies,” a SEM can be used at a magnification of ×2000, for example.

The “thickness of the fibrous bodies” and the “length of the area of the fibrous bodies” are determined in the following manner.
(a1) STEP 1

The peeling surface, on the dielectric sheet side, generated in the peel strength test at 180 degrees is observed from above (open side) under a SEM such that the line of the sight of the observation is almost parallel to the normal vector of the peeling surface, and a fibrous body is specified. The fibrous body three-dimensionally expands in fact, but is grasped as a line (projected line) in a SEM image, or in other words, a two-dimensional projection image. When the “thickness of the fibrous body” and the “length of the area of the fibrous bodies” and the “average space between the areas of the at least part of the fibrous bodies,” which will described next, are measured, measurement is made on the fibrous bodies (truly, the projected lines of the fibrous bodies) in the SEM image. It is necessary that the magnification of the SEM should be enough to see the fibrous body clearly. Specifically, a suitable magnification is ×1000 to ×3000, particularly ×2000.
(a2) STEP 2

The area of a fibrous body having a thickness of 0.1 μm or more and 3.0 μm or less is specified. The length of the area is measured and used as the length of the area of the fibrous body.

The “average space between the areas of the at least part of the fibrous bodies” is determined in the following manner.
(b1) STEP 1

A fibrous body is specified in the same manner as in “a1” described above.
(b2) STEP 2

An area of a fibrous body is specified, the area having a thickness of 0.1 μm or more and 3.0 μm or less and a length of 50 μm or more and 5000 μm or less.
(b3) STEP 3

The segment of the approximate line (approximate line segment) of the area of the fibrous body specified in (b2) is determined. The approximate line segment is a segment in the SEM image such that the sum of squares of the lengths from the points defining the area of the fibrous body specified in STEP 2 to a line segment is minimum when the points are each moved in the direction of the normal vector of the line segment.
(b4) STEP 4

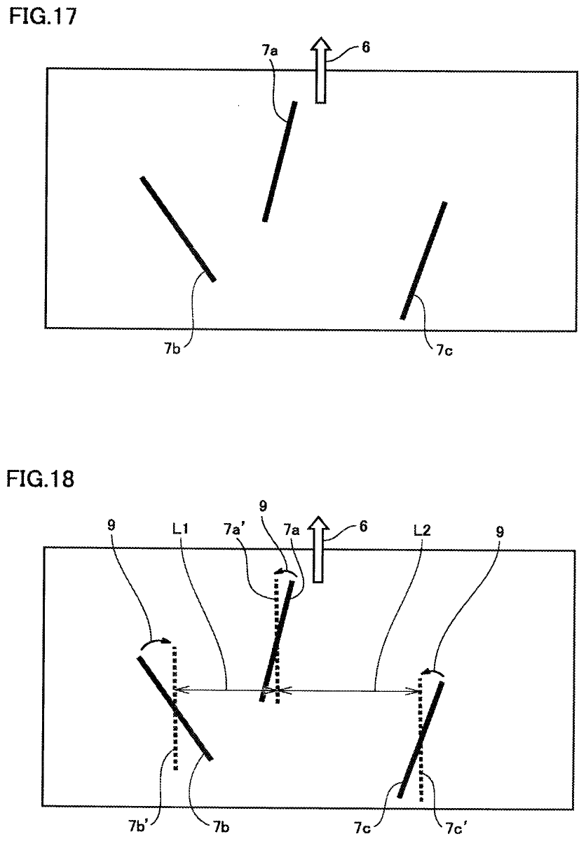

The direction of the pulling of the test sample in the peel strength test at 180 degrees is considered as the vector projected onto the SEM image (the peeling vector). The approximate line segment of the area of the fibrous body is rotated without changing the center of balance such that the angle between the approximate line segment and the peeling vector is zero degrees (hereinafter, the approximate line segment rotated such that the angle between the approximate line segment and the peeling vector is zero degrees is also referred to as the rotated line segment). Then, when each rotated line segment is moved in the normal direction of the peeling vector, the rotated line segment at least partly overlaps other rotated line segments. Among the other rotated line segments, an adjacent rotated line segment is specified, and the adjacent rotated line segment is a line segment such that the moving distance to overlap it is the shortest. The moving distance to overlap is used as the adjacent distance. The average value of the adjacent distances of all rotated line segments is used as the average space between the areas of the at least part of the fibrous bodies. For example, in a case where approximate line segments present in a SEM image are approximate line segments 7a, 7b, and 7c as shown in FIG. 17, approximate line segments 7a, 7b, and 7c are rotated in the direction of arrow 9 without changing the center of balance so that the angle between the approximate line segment and the peeling vector is zero degrees. As a result, shown in FIG. 18, approximate line segment 7a is arranged at the position of rotated line segment 7a′, which is represented by a dotted line; approximate line segment 7b is arranged at the position of rotated line segment 7b′, which is represented by a dotted line; and approximate line segment 7c is arranged at the position of rotated line segment 7c′, which is represented by a dotted line. Distance L1 between rotated line segment 7a′ and rotated line segment 7b′ is shorter than distance L2 between rotated line segment 7a′ and rotated line segment 7c′. Therefore, the adjacent rotated line segment of rotated line segment 7a′ is rotated line segment 7b′, and the adjacent distance of rotated line segment 7a′ is distance L1.

### Details of Embodiments

The dielectric sheet, the substrate for a high frequency printed wiring board, and the high frequency printed wiring board according to the embodiments of the present disclosure will now be described in detail with reference to drawings appropriately. In the drawings of the present disclosure, the same reference signs represent the same parts or the corresponding parts. For the sake of plainness and simplicity of the drawings, the relation between the dimensions, including the length, width, thickness, and depth, is appropriately modified and does not necessarily present the actual relation between the dimensions. The contents of the drawings do not limit the content of the present disclosure.

### <Dielectric Sheet>

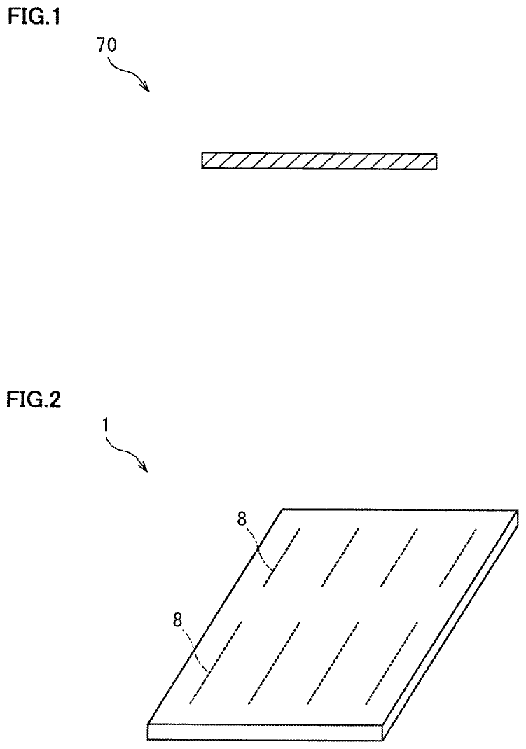

FIG. 1 is a schematic cross-sectional view of the dielectric sheet. Dielectric sheet 70 includes a polytetrafluoroethylene and spherical inorganic fillers. Since the polytetrafluoroethylene has a small dielectric constant, dielectric sheet 70 is suitable for an insulation base material for a substrate for a high frequency printed wiring board for high frequency signal processing. Dielectric sheet 70 also has favorable workability in, for example, boring holes, since dielectric sheet 70 includes the spherical inorganic fillers.

The mass ratio of the inorganic fillers to the polytetrafluoroethylene is 1.3 or more, preferably 1.5 or more, and more preferably 1.6 or more, in terms of its lower limit. On the other hand, the mass ratio of the inorganic fillers is preferably 2.2 or less, and more preferably 2.0 or less, in terms of its upper limit. Due to a mass ratio of the inorganic fillers to the polytetrafluoroethylene of 1.3 or more, dielectric sheet 70 has a decreased coefficient of linear expansion, and thus, dielectric sheet 70 has improved dimension stability against temperature changes. In addition, the peeling mode in the 180-degree peel test easily results in cohesion failure. On the other hand, if the mass ratio of the inorganic fillers is more than the above-described upper limit, dielectric sheet 70 is brittle so that the ease to handle and the peel strength may be decreased.

The inorganic fillers have an average particle diameter of 0.3 μm or more and 4.0 μm or less. Due to this, dielectric sheet 70 is excellent in the coefficient of linear expansion and workability, and also evenness of the thickness of dielectric sheet 70 as a thin film can be ensured. The average particle diameter of the inorganic fillers is preferably 0.4 μm or more, more preferably 0.5 μm or more, and even more preferably 1.0 μm or more, in terms of its lower limit. When the average particle diameter of the inorganic fillers is equal to or more than the above-described lower limit, dielectric sheet 70 is excellent in the coefficient of linear expansion and workability. The average particle diameter of the inorganic fillers is preferably 3.5 μm or less, more preferably 3.0 μm or less, and even more preferably 2.0 μm or less, in terms of its upper limit. When the average particle diameter of the inorganic fillers is equal to or less than the above-described upper limit, the evenness of the thickness of dielectric sheet 70 as a thin film can be ensured. The average particle diameter of the inorganic fillers is preferably 0.4 μm or more and 3.5 μm or less, more preferably 0.5 μm or more and 3.0 μm or less, and even more preferably 1.0 μm or more and 2.0 μm or less. A plurality of inorganic fillers having different average particle diameters within the above-described range may be used in combination.

The inorganic fillers include a silica filler. The silica filler included in the inorganic fillers has a small dielectric constant and is inexpensive, and a spherical silica filler is easily manufactured; accordingly, the dielectric sheet has a decreased dielectric constant and is inexpensive.

No regard may be made for the silica filler in terms of a natural product or synthetic product, a crystalline or amorphous product, or a product by a dry or wet manufacturing process. However, the silica filler is preferably a synthetic silica filler by the dry manufacturing process in view of availability and product quality.

The silica filler preferably has, on the surface thereof, a hydrocarbon group having 4 or more carbon atoms. Examples of the hydrocarbon group include an alkyl group, a vinyl group, and an aryl group. Among these, the alkyl group is preferable. When the silica filler has, on the surface thereof, an alkyl group having 4 or more carbon atoms, the adhesive force between the silica filler and the polytetrafluoroethylene can be large to obtain a large peel strength. In view of the binding of the alkyl group to the surface of the silica filler, the number of carbon atoms is more preferably 5 or more so as to facilitate the interaction to the polytetrafluoroethylene. On the other hand, the number of carbon atoms is preferably 10 or less in terms of its upper limit. The alkyl group is preferably a linear alkyl group. Examples of the alkyl group having 4 or more carbon atoms include a butyl group, a pentyl group, a hexyl group, a heptyl group, an octyl group, a nonyl group, and a decyl group.

The inorganic fillers may include a spherical inorganic filler other than the silica filler. The inorganic fillers may also include a non-spherical inorganic filler as long as the workability is not impaired. Examples of the inorganic filler other than the silica filler include aluminum oxide, magnesium oxide, calcium oxide, talc, barium sulfate, boron nitride, zinc oxide, potassium titanate, glass, titanium oxide, and mica.

The content of the silica filler in the inorganic fillers is preferably 70 mass % or more, more preferably 80 mass % or more, even more preferably 90 mass % or more, and particularly preferably 100 mass %, in terms of its lower limit. When the inorganic fillers include a silica filler, the content of the silica filler in the inorganic fillers being 70 mass % or more, the dielectric sheet can have a more decreased coefficient of linear expansion and therefore improved dimension stability, and accordingly, the dielectric sheet can have improved characteristics in high frequencies. A larger content of the silica filler in the inorganic fillers is more preferable, and accordingly, the content of the silica filler is preferably 100 mass % or less in terms of its upper limit. The content of the silica filler in the inorganic fillers is preferably 70 mass % or more and 100 mass % or less.

In dielectric sheet 70, part of the polytetrafluoroethylene is present in the form of a plurality of fibrous bodies.

The fibrous bodies are formed so as to have oriented components in the thickness direction of the dielectric sheet. In a 180-degree peel test of the dielectric sheet after the dielectric sheet is allowed to strongly adhere to an adhered, the fibrous bodies act to resist against the peeling force applied mainly in the thickness direction, to thereby obtain a large peel strength. The fibrous bodies encompass a plurality of adjacent fibers that looks as if they form into a thick fiber in a SEM image. In the peel test, the fibrous bodies are extended and oriented in one direction along the peeling surface (the direction in which the test sample is pulled). The extended fibrous bodies after the peel test are filamentous and are each in the form of an almost straight line in plan view. The “almost straight line” encompasses a fibrous body in the form of a straight line, and also a fibrous body with minute irregularities when a straight line is drawn along the fibrous body, the irregularities straying from the straight line, for example.

In a SEM image of the dielectric sheet's surface observed after a 180-degree peel test, at least part of fibrous bodies among the fibrous bodies has areas with a thickness of 0.1 μm or more and 3.0 μm or less and a length of 50 μm or more and 5000 μm or less. The average space between the areas of the at least part of fibrous bodies is 10 μm or less, and preferably 7 μm or less, in terms of its upper limit. If the average space between the areas of the fibrous bodies, observed in the surface of the dielectric sheet after a 180-degree peel test, is more than the above-described upper limit, the extent of the fibrillization of the polytetrafluoroethylene is not sufficient so that the peel strength of the dielectric sheet in the thickness direction may be insufficient. On the other hand, the average space between the areas of the at least part of the fibrous bodies is preferably 1 μm or more, in terms of its lower limit.

The 180-degree peel test is carried out in accordance with JIS-K6854-2 (1999) to measure the peel strength. A polyimide tape having a thickness of 66 μm with a base material having a thickness of 25 μm (“P221” manufactured by Nitto Denko Corporation.) is attached to the surface of a measurement sample prepared by laying copper foil on the dielectric sheet. Then, the copper foil is pulled at 50 mm/min from the point of the copper foil attached to the polyimide tape as the starting point, and the strength when peeled at 180 degrees is measured. The value of the peel strength (N/cm) in the 180-degree peel test is a value obtained by dividing the found value obtained in the test by the width of the test sample (copper foil).

Dielectric sheet 70 may include an additional fluororesin other than the polytetrafluoroethylene. In this case, the upper limit of the content of the other fluororesin in dielectric sheet 70 is preferably 10 mass %, and more preferably 5 mass %.

Dielectric sheet 70 may include, as optional components, a flame retardant, a flame retardant aid, a pigment, an antioxidant, a reflective agent, a concealing agent, a lubricant, a processing stabilizer, a plasticizer, and a foaming agent, for example. In this case, the upper limit of the content of the optional components in dielectric sheet 70 is preferably 25 mass %, and more preferably 10 mass %.

The peel strength in the 180-degree peel test is preferably 10 N/cm or more, and more preferably 12 N/cm or more, in terms of its lower limit. When the peel strength in the 180-degree peel test is equal to or more than the above-described lower limit, dielectric sheet 70 has improved durability and anti-workability. The peeling mode in the 180-degree peel test is preferably cohesion failure, and not interfacial failure from the copper foil, or interfacial failure from an adhesive layer when the adhesive layer is provided on the copper foil. This is because a stable peel strength can be secured irrespective of the state of the surface of the copper foil or the state of the surface of the adhesive layer. In interfacial failure, the ratio of the polytetrafluoroethylene in the peeling surface is larger than the ratio of polytetrafluoroethylene in the whole dielectric sheet because the ratio of a silica filler is small in the interface.

The average thickness of dielectric sheet 70 is preferably 20 μm or more, more preferably 50 μm or more, even more preferably 80 μm or more, and even more preferably 100 μm or more, in terms of its lower limit. On the other hand, the average thickness of dielectric sheet 70 is preferably 1000 μm or less, more preferably 500 μm or less, and even more preferably 300 μm or less, in terms of its upper limit. If the average thickness is less than the above-described lower limit, dielectric sheet 70 may have insufficient mechanical strength, and also is difficult to handle. In addition, an influence of the error in the dimension on the characteristics of the electric circuit in high frequencies is large, and accordingly, circuit design and manufacture of circuit components may be difficult. On the other hand, if the average thickness is more than the above-described upper limit, a resulting substrate for a high frequency printed wiring board may have too large a thickness, and also dielectric sheet 70 may have insufficient flexibility in a case where flexibility is required of dielectric sheet 70. The “average thickness” here refers to the distance between the average line of the interface on the front side and that on the back side in the cross section when the object of interest is cut in the thickness direction. The “average line” refers to an imagery line drawn along the interface, wherein the total area of peaks defined by the interface and the imagery line (the total area on the upper side than the imagery line) is equal to the total area of troughs defined by the interface and the imagery line (the total area on the lower side than the imagery line). The difference between the maximum and the minimum of the thickness of dielectric sheet 70 is preferably within ±10 μm, more preferably ±5 μm, and even more preferably ±2 μm, in 1 m² of dielectric sheet 70. If the difference is outside the above-described range, circuit design and manufacture of circuit components may be difficult.

### [Method for Manufacturing Dielectric Sheet]

The method for manufacturing the dielectric sheet is not particularly limited, and various methods can be used. Examples of the method for manufacturing the dielectric sheet include: a method including pressing a resin composition for dielectric sheets to solidify the resin composition into a columnar shape, the resin composition including a polytetrafluoroethylene powder and spherical inorganic fillers, and rotary cutting the resin column into a continuous sheet; a method including dispersing a resin composition for dielectric sheets in a solvent to obtain a slurry and spreading the slurry into a sheet form, followed by drying; a method including allowing a resin composition for dielectric sheets to pass between mill rolls to shape the resin composition into a sheet form; and a method including extrusion molding a resin composition for dielectric sheets. Among these, preferred are the method including allowing a resin composition for dielectric sheets to pass between mill rolls to shape the resin composition into a sheet form and the method including extrusion molding a resin composition for dielectric sheets, which can give a shaped product in a sheet form having excellent mechanical strength and an accurate thickness while fibrous bodies of the polytetrafluoroethylene are formed. In comparison of the extrusion molding and the rolling with each other, the rolling is superior in terms of accuracy of formation of thin sheets, and accordingly, it is desirable that a resin composition for dielectric sheets should by first extrusion molded, followed by rolling the resulting extrusion molded product.

The present inventors have found that in a case where inorganic fillers have an average particle diameter of 0.3 μm or more and 4.0 μm or less as in the dielectric sheet, it is effective for obtaining a large peel strength to generate fibrous bodies and process so as to include fibrous bodies having oriented components in the thickness direction. For processing so as to include fibrous bodies having oriented components in the thickness direction, the following methods can be used, for example: a method involving selection of manufacturing conditions such that the shear force in the extrusion molding direction or the rolling direction is as small as possible; a method in which the shape of the flow channel of the die for extrusion molding is a shape that generates a turbulent flow; a method including collecting the extrusion molded product and further extrusion molding it; and a method including laying rolled sheets one on top of another and again rolling the resultant.

The method for manufacturing the dielectric sheet preferably further includes mixing materials and removing an auxiliary.

Examples of steps in one embodiment of the method for manufacturing the dielectric sheet will be described below.

### (Mixing Materials)

In this step, a resin composition for dielectric sheets is manufactured, the resin composition including a polytetrafluoroethylene powder and spherical inorganic fillers. An auxiliary (liquid lubricant) is preferably added to the resin composition for dielectric sheets.

The method for mixing is not particularly limited as long as the materials can be mixed with each other. Examples of the method for mixing include a dry method, i.e., a method including mixing a polytetrafluoroethylene powder, spherical inorganic fillers, and an auxiliary; and a wet method, i.e., a method including mixing a polytetrafluoroethylene dispersion and an inorganic filler-dispersing liquid. In the dry method, for example, the polytetrafluoroethylene powder, the inorganic fillers, and the auxiliary can be placed in a sealable container, and the container can be rotated to mix the materials. In the wet method, for example, while the polytetrafluoroethylene dispersion is stirred at high speed, a surfactant and the inorganic fillers are added thereto to create an inorganic filler-dispersing state, and a flocculant is added thereto to flocculate the polytetrafluoroethylene to thereby obtain a mixture of a polytetrafluoroethylene impalpable powder and an inorganic filler impalpable powder. While the mixture of the impalpable powders is pulverized and mixed, the auxiliary can be added thereto to thereby mix the materials.

The polytetrafluoroethylene powder is not particularly limited as long as it can be used for extrusion molding, and a fine powder is preferably used. The fine powder is a powder that is obtained by flocculating and drying polytetrafluoroethylene dispersion obtained by emulsion polymerization of tetrafluoroethylene and having an average particle diameter of 0.1 μm to 0.5 μm. The average particle diameter of the powder is, for example, 20 μm to 1000 μm. The upper limit of the average particle diameter of the polytetrafluoroethylene powder is preferably 700 μm, more preferably 500 μm, and even more preferably 400 μm, in view of ease of creating a uniform fine dispersing-state with the inorganic fillers. The lower limit of the average particle diameter of the powder is preferably 50 μm, more preferably 100 μm, and even more preferably 200 μm, in view of allowing fibrillization of the polytetrafluoroethylene to moderately proceed.

The auxiliary is not particularly limited as long as it wets the polytetrafluoroethylene to facilitate its plastic deformation and can be easily removed by heating after repeating of rolling, which will be described later. Examples thereof include petroleum solvents such as solvent naphtha and white oil, hydrocarbon oils such as undecane, aromatic hydrocarbons such as toluol and xylol, alcohols, ketones, esters, silicone oil, fluorochlorocarbon oil, a solution obtained by dissolving a polymer such as polyisobutylene or polyisoprene in any of these solvents, a mixture of two or more thereof, and water or an aqueous solution containing a surfactant. A single component is more preferable than a mixture because the former enables uniform mixing. The amount of the auxiliary is not particularly limited as long as the amount is sufficient to wet the polytetrafluoroethylene. The mass ratio of the auxiliary to the polytetrafluoroethylene is preferably 0.1 or more and 0.8 or less, more preferably 0.2 or more and 0.7 or less, and even more preferably 0.3 or more and 0.6 or less.

### (Extrusion Molding)

In this step, the resin composition for dielectric sheets, including the polytetrafluoroethylene powder and the spherical inorganic fillers, is extrusion molded at a temperature equal to or lower than the melting point of the polytetrafluoroethylene.

The temperature of the extrusion molding is equal to or lower than the melting point of the polytetrafluoroethylene. Specifically, the upper limit of the temperature of the extrusion molding is preferably 100° C. The temperature of the extrusion molding is also preferably equal to or more than the transition temperature of the polytetrafluoroethylene, which is near room temperature. Specifically, the lower limit of the temperature of the extrusion molding is preferably 40° C. When the temperature of the extrusion molding is within the above-described range, the extrusion molding can be carried out stably.

The molded product obtained in this step by extrusion molding the resin composition for dielectric sheets preferably has a flatten shape, such as a rectangle and an oval, in a cross section by a plane perpendicular to the extrusion molding direction. This is because a molded product having such a shape is easy to introduce to mill rolls in the rolling and gives excellent uniformity of the sheet after the rolling. The shape in the cross section is particularly preferably a rectangle.

It is generally suitable that the reduction ratio used in extrusion molding of a polytetrafluoroethylene should be 20 or more and 1000 or less. As shown in FIG. 2, fibrous bodies in the extruded direction are formed in the extrusion molded product by the shear force applied when molded. In this step, the upper limit of the reduction ratio is preferably 15 and preferably 10, and the reduction ratio is more preferably 8 or less and even more preferably 6 or less. When the reduction ratio, in terms of its upper limit, in the extrusion molding is within the above-described range, the tendency for the fibrous bodies of the polytetrafluoroethylene to orient in the extrusion molding direction is suppressed to prevent excessive increase of the strength in the extrusion molding direction, so that the frictional force between the inner wall of the extruder and the resin composition for dielectric sheets can be reduced to carry out the extrusion molding at a lower pressure without splits or clogging at the end portion. Since the tendency for the fibrous bodies to orient in the extrusion molding method is suppressed, the ratio of the oriented components of the fibrous bodies in the thickness direction can become larger. The “reduction ratio” is a value obtained by dividing the maximum cross-sectional area by the minimum cross-sectional area among the cross-sectional areas of the flow channel through which the object to be extrusion molded passes in the extrusion molding.

### (First Rolling)

As shown in FIG. 2, the extrusion molded product obtained by the extrusion molding is rolled to form a sheet body 1. When rolled, a shear force is applied to sheet body 1 to form a plurality of fibrous bodies 8 of the polytetrafluoroethylene in sheet body 1. Fibrous bodies 8 that are formed in this rolling step are to be formed such that the longitudinal directions thereof are generally arranged in the direction of the rolling (hereinafter, also referred to as “the rolling direction”) along the surface of sheet body 1. Fibrous bodies 8 that have been formed before this rolling step are also re-arranged such that fibrous bodies 8 with their longitudinal directions arranged in the rolling direction are increased. In FIG. 2, fibrous bodies 8 are shown simply such that they are arranged in the rolling direction. The “longitudinal direction” of fibrous body 8 means the direction along the extending direction of fibrous body 8.

The lower limit of the rolling reduction in the rolling is preferably 0.93, more preferably 0.95, and even more preferably 0.97. When the rolling reduction, in terms of its lower limit, is within the above-described range, the rolling facilitates the fibrillization of the polytetrafluoroethylene to enhance its extension so that a dielectric sheet having favorable resistance against bending can be obtained. In addition, it eliminates the necessity to promote the fibrillization of the polytetrafluoroethylene in the extrusion molding, which needs a high pressure, and accordingly, the extrusion molding can be carried out at a low pressure. On the other hand, the upper limit of the rolling reduction in the rolling is preferably 0.99, and more preferably 0.98. When the rolling reduction, in terms of its upper limit, is within the above-described range, the degree of processing in the rolling is kept low, so that variation in the characteristics, including the thickness and the mechanical strength, due to excessive processing can be suppressed. The “rolling reduction” means the change rate of the thickness of the sheet represented by (h0−h1)/h0, wherein h0 is the thickness of the sheet before the rolling and h1 is the thickness of the sheet after the rolling (after the last stage in a case where reduction is carried out in two or more stages). A larger numerical value of the rolling reduction means that the rolling gives a larger change rate of the thickness of the sheet.

The rolling temperature in this step is preferably 30° C. or more and 100° C. or less. 30° C. is higher than the transition temperature of the polytetrafluoroethylene, which is near room temperature, and when the rolling temperature is 30° C. or more, uniform rolling can be easily achieved. When the rolling temperature is 100° C. or less, at which the extent of vaporization of the auxiliary is small, uniform rolling can be easily achieved.

### (Repeating of Rolling)

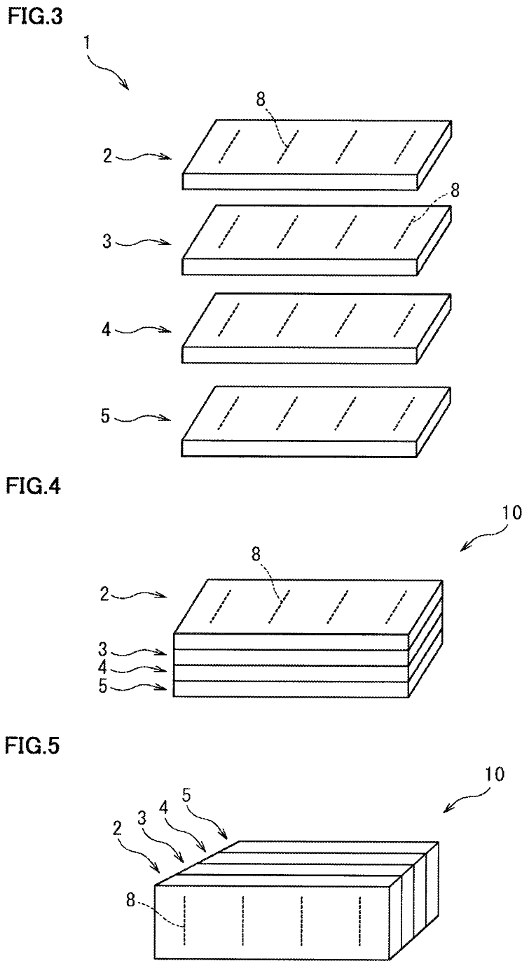

As shown in FIG. 3, sheet body 1 is, for example, divided into quarters to prepare a divided body 2, a divided body 3, a divided body 4, and a divided body 5. The number of divisions is not particularly limited in the dividing.

Next, as shown in FIG. 4, divided body 2, divided body 3, divided body 4, and divided body 5 are placed on top of each other with the direction of the fibrous bodies 8 maintained, to thereby prepare a laminate 10. FIG. 3 and FIG. 4 shows a process in which laminate 10 is prepared from the divided bodies obtained by cutting sheet body 1; however, the process for preparing laminate 10 is not limited thereto. For example, sheet body 1 may be folded in a zigzag manner without cutting sheet body 1 to prepare laminate 10.

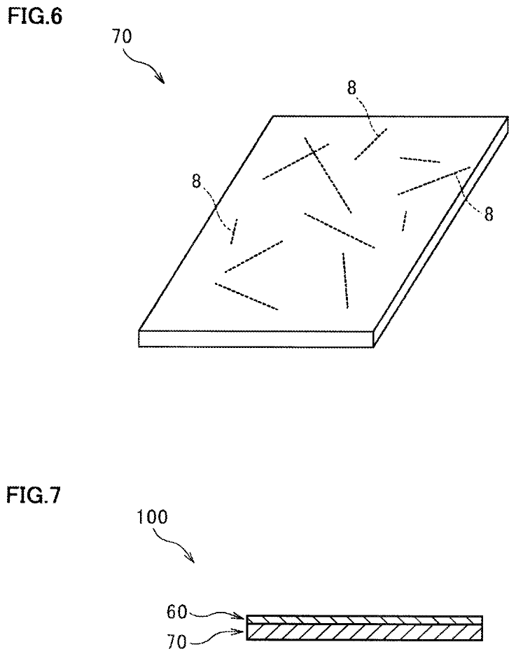

Next, laminate 10 is rotated 90 degrees so that the original upper side and the bottom side become the lateral sides, as shown in FIG. 5, and laminate 10 after rotation is again rolled. Rolling, dividing, placing on top of each other, rotating, and rolling, as described above, were carried out repeatedly several times to manufacture dielectric sheet 70 in which the directions of a plurality of fibrous bodies 8 are different with each other as shown in FIG. 6.

In this step, since laminate 10 is rotated 90 degrees and rolled in this manner, the first dielectric sheet is rolled in the thickness direction thereof. Then, on manufactured sheet body 1, dividing, placing on top of each other, rotating, and rolling were carried out repeatedly to conduct rolling several times. By repeating these sub-steps in such a manner in this step, fibrillization is promoted to increase fibrous bodies 8 of the polytetrafluoroethylene, and also, anisotropic arrangement of these fibrous bodies 8 and the oriented components in the thickness direction of the dielectric sheet are created (see FIG. 6). Accordingly, the peel strength of dielectric sheet 70 is improved.

### (Removing Auxiliary)

In this step, the sheet body formed by the repeating of the rolling is preferably dried to remove the auxiliary (liquid lubricant). The method for removing the auxiliary is preferably drying, which is simple. The drying temperature and time may be appropriately selected from a temperature range lower than the melting point of the polytetrafluoroethylene according to the characteristics of the auxiliary.

The dielectric sheet is excellent in the characteristics in high frequencies, workability, and the peel strength. The dielectric sheet is suitable as a base film for a substrate for a high frequency printed wiring board.

### <Substrate for High Frequency Printed Wiring Board>

FIG. 7 is a schematic cross-sectional view of the substrate for a high frequency printed wiring board. As shown in FIG. 7, substrate for a high frequency printed wiring board, 100 includes dielectric sheet 70 and copper foil 60 directly or indirectly laid on the surface of dielectric sheet 70. In other words, substrate for a high frequency printed wiring board, 100 includes a copper clad laminate (CCL).

Details of features of dielectric sheet 70 are as described above.

### [Copper Foil]

Copper foil 60 is, for example, etched to thereby form a conductive pattern of a high frequency printed wiring board.

Copper foil 60 is used as a conductive layer, and worked into various patterns by, for example, etching in manufacture of a high frequency printed wiring board.

Copper foil 60 is not particularly limited as long as it is copper foil usable for high frequency printed wiring boards, and copper foil 60 may be selected appropriately according to the required characteristics and others. The copper purity of copper foil 60 is preferably 99.5 mass % or more, and more preferably 99.8 mass % or more, in terms of its lower limit. The purity is preferably 99.999 mass % or less, in terms of its upper limit. When the purity is equal to or more than the above-described lower limit, copper foil 60 can have decreased resistance to thereby further suppress transmission loss. On the other hand, a purity more than the above-described upper limit may lead to increase in cost. It is preferable to carry out, on the surface of copper foil 60, treatment common as a surface treatment for copper foil for high frequency printed wiring boards, including treatment for the purpose of rust-proofing and treatment for the purpose of improving adhesiveness. These treatments are achieved by forming a layer made of Zn, Ni, Cr, Si, or others on the outer surface of copper foil 60.

Copper foil 60 preferably has a maximum height of roughness profile, Rz, as defined in JIS-B0601 (1982), of 2.0 μm or less, more preferably 1.5 μm or less, and even more preferably 1.0 μm or less, in terms of its upper limit. When the maximum height of roughness profile, Rz of copper foil 60 is equal to or less than the above-described upper limit, unevenness of the part where high frequency signals are concentrated is small by the skin effect, so that a current easily flows linearly; and accordingly, transmission loss can be further suppressed. On the other hand, the lower limit of the maximum height of roughness profile, Rz is not particularly limited, and the Rz is generally about 0.1 μm or more.

The average thickness of copper foil 60 is preferably 5 μm or more, and more preferably 10 μm or more, in terms of its lower limit. On the other hand, the average thickness is preferably 100 μm or less, and more preferably 75 μm or less, in terms of its upper limit. When the copper foil is thick, the capacity of the current that can be allowed to flow is larger, and in addition, heat conductivity is favorable, advantageously. However, the average thickness is preferably 20 μm or less, and more preferably 15 μm or less, in terms of its upper limit, when an emphasis is put on the needs for multi-layering and reduction in thickness of high frequency printed wiring boards.

Substrate for a high frequency printed wiring board, 100 may include an additional layer other than dielectric sheet 70 or copper foil 60.

Copper foil 60 in substrate for a high frequency printed wiring board, 100 may be laid on the surface on at least one side of dielectric sheet 70 via an intermediate layer such as a known adhesive layer. For example, in an embodiment, the adhesive layer may be laid on dielectric sheet 70, and copper foil 60 may be adhered to dielectric sheet 70 via the adhesive layer.

### [Method for Manufacturing Substrate for High Frequency Printed Wiring Board]

A method for manufacturing a substrate for a high frequency printed wiring board includes laying copper foil directly or indirectly on the surface of the dielectric sheet manufactured by the above-described method for manufacturing the dielectric sheet. Since the method for manufacturing a substrate for a high frequency printed wiring board includes laying copper foil directly or indirectly on the surface of the dielectric sheet excellent in the characteristics in high frequencies, workability, and peel strength, the method can easily and surely manufacture a substrate for a high frequency printed wiring board, the substrate being excellent in the characteristics in high frequencies, workability, and peel strength and having improved durability.

Except for the laying the copper foil, the content of the method for manufacturing a substrate for a high frequency printed wiring board is the same as that of the method for manufacturing the dielectric sheet, and accordingly descriptions therefor are omitted.

### (Laying Copper Foil)

In this step, copper foil is laid directly or indirectly on the surface of the dielectric sheet formed by the repeating of the rolling. Examples of the method for laying copper foil include a method involving bonding the dielectric sheet and the copper foil to each other by thermocompression. However, if the dielectric sheet and the copper foil without any treatment are bonded to each other by thermocompression, there is a concern for small adhesiveness between them. Accordingly, preferred are, for example, a method including carrying out surface treatment, such as corona treatment, plasma treatment, or silane coupling treatment, on the surface of the dielectric sheet or the copper foil, and then bonding them by thermocompression; and a method including forming a thin film made of an adhesive composition on the surface of the dielectric sheet or the copper foil, or laying a film formed from an adhesive composition between the dielectric sheet and the copper foil, to bonding them via the adhesive composition by thermocompression.

The temperature of the bonding by thermocompression is preferably 320° C. or more, and more preferably 330° C. or more, in terms of its lower limit. The temperature of the bonding by thermocompression is preferably 390° C. or less, and more preferably 380° C. or less, in terms of its upper limit. If the temperature of the bonding by thermocompression is less than the above-described lower limit, deformation of the polytetrafluoroethylene may be difficult to fail to obtain a favorable mechanical strength. If the temperature of the bonding by thermocompression is more than the above-described upper limit, a trace amount of corrosive gas may be generated by decomposition of the polytetrafluoroethylene.

In the laying the copper foil in the method for manufacturing a substrate for a high frequency printed wiring board, it is preferable that the copper foil should be laid on the surface of the dielectric sheet via the adhesive layer, the adhesive layer including a thermoplastic fluororesin as a main component. In the laying the copper foil, when the copper foil is laid on the surface of the dielectric sheet via the adhesive layer including a thermoplastic fluororesin as a main component, copper foil with small roughness and the dielectric sheet can be adhered to each other firmly while the favorable characteristics in high frequencies due to the fluororesin are secured. The “main component” refers to the component whose content is largest, and for example, a component whose content is 60 mass % or more.

The adhesive layer may be provided by laying the adhesive layer on the surface of the dielectric sheet or may be provided by laying the adhesive layer on the surface of the copper foil, before the laying the copper foil.

The thermoplastic fluororesin is preferably a fluororesin having a thermal softening temperature of 320° C. or less in view of obtaining favorable adhesiveness, and examples thereof include perfluoroalkoxyalkane (PFA) and perfluoroethylene propene copolymer (FEP).

The thickness of the adhesive layer is preferably 0.1 μm or more, and more preferably 0.5 μm or more, in terms of its lower limit. The thickness of the adhesive layer is preferably 5 μm or less, and more preferably 2 μm or less, in terms of its upper limit. When the thickness of the adhesive layer is within the above-described range, the copper foil and the dielectric sheet can be adhered to each other firmly while the coefficient of linear expansion of the substrate as a whole is kept small. Since substrate for a high frequency printed wiring board, 100 includes

dielectric sheet 70, the substrate 100 is excellent in the characteristics in high frequencies, workability, and peel strength and has improved durability. Substrate for a high frequency printed wiring board, 100 can be used as a substrate for a high frequency printed wiring board for, for example, a subtractive method or semi-additive method.

### <High Frequency Printed Wiring Board>

A high frequency printed wiring board according to another aspect of the present disclosure includes the substrate for a high frequency printed wiring board and therefore the dielectric sheet described above. Since the high frequency printed wiring board includes the substrate for a high frequency printed wiring board, the high frequency printed wiring board is excellent in the characteristics in high frequencies, workability, and peel strength.

The high frequency printed wiring board includes, for example, a patterned conductive layer. The conductive layer of the high frequency printed wiring board is formed by etching the copper foil into a pattern. The method for etching is not particularly limited. For example, in a case where a subtractive method is used as the etching method, the conductive layer can be etched through a mask for a pattern put thereon to thereby obtain a high frequency printed wiring board with a circuit formed. Another example of the method for etching is a semi-additive method. Still another example is a method including forming a conductive layer on the dielectric sheet by an additive method. The high frequency printed wiring board is suitably used for, for example, communication devices used in high frequencies. In the method for manufacturing the high frequency printed wiring board, the dielectric sheet or the substrate for a high frequency printed wiring board may be laid on another printed wiring board, followed by forming a conductive layer of the dielectric sheet or the substrate for a high frequency printed wiring board.

### Other Embodiments

It should be appreciated that the embodiments disclosed herein are illustrative in every sense and are not limitative. The scope of the present disclosure is not limited to the features of the above-described embodiments but is presented by the claims, and it is intended that equivalent meanings to the claims and all modifications within the scope are encompassed.

In the substrate for a high frequency printed wiring board, copper foil may be laid on one side of the dielectric sheet as in the above-described embodiment, or copper foil may be laid on each of both sides of the dielectric sheet.

The substrate for a high frequency printed wiring board may be used as a substrate for a flexible high frequency printed wiring board or a substrate for a rigid high frequency printed wiring board.

### EXAMPLES

The present disclosure will now be described specifically by way of Examples, but the present disclosure is not limited to these Examples.

### [Dielectric Sheet No. 1 to No. 7]

### (1) Mixing Materials

A polytetrafluoroethylene having an average particle diameter of 500 μm, a silica filler having an average particle diameter shown in Table 1, and naphtha as an auxiliary each in the amount shown Table 1 were placed in a container. Hexyl groups had been given to the surface of the silica filler by silane coupling treatment. The amount of naphtha placed corresponds to 17 mass % based on the total of the other materials. The container was rotated at 25° C. at a speed of 5 rpm for 100 minutes to mix the materials. The mass ratio of the silica filler to the polytetrafluoroethylene was as shown in Table 1.

### (2) Extrusion Molding

Next, the resin composition for dielectric sheets obtained in the mixing of the materials was extrusion molded with a die. The temperature of the die for extrusion molding was 45° C. The reduction ratio was 7. The diameter o of the plunger of the extruder was 50 mm, and the pressure of this extruder was 15 MPa when molding.

### (3) Rolling

The extrusion molded product having a thickness of 4 mm and a length of 300 mm was sandwiched between two carrier films (polyethylene terephthalate (PET) having a thickness of 125 μm, each), and the resultant was allowed to pass through between two mill rolls each having a diameter ø of 200 mm and a width of 360 mm to obtain a dielectric sheet having a thickness of 500 μm or 125 μm. The temperature of the mill rolls was 55° C., and the rolling speed was 1 m/min. The rolling directions were the extruded direction of the extrusion molded product and the width direction perpendicular to the extruded direction.

### (4) Repeating of Rolling

The dielectric sheet having a thickness of 500 μm obtained by the rolling was folded in a zigzag manner with 1-cm intervals in the rolling direction. In other words, “the dielectric sheet was folded along a line 1 cm apart from the edge so that the first side was the inner side; folded along a line 2 cm apart from the edge so that the first side was the outer side; and folded along a line 3 cm apart from the edge so that the first side was the inner side” and such a process was repeated to obtain a laminate, which was a dielectric sheet folded in a zigzag manner. Next, the laminate of the dielectric sheet was allowed to pass through between the two mill rolls in the thickness direction of the dielectric sheet to obtain a dielectric sheet having a thickness of 500 μm, and on this dielectric sheet, the process of folding in a zigzag manner was repeated. By repeating the process of folding in a zigzag manner zero to several times, a desirable state of fibrous bodies can be obtained. In the final rolling, the thickness was adjusted to 125 μm to obtain a dielectric sheet having an average thickness of 125 μm.

### [Evaluations]

For dielectric sheets No. 1 to 7 as described above, the following evaluations were carried out.

### (Peel Strength in 180-Degree Peel Test)

The peel strength in the 180-degree peel test was measured by the method described hereinabove. The value of the peel strength (N/cm), described in Table 1, in the 180-degree peel test is a value obtained by dividing the value found in the test by the width of the test sample. The peeling modes were all cohesion failure. In addition, the thickness, length, and average space of the fibrous bodies observed in each surface of dielectric sheets No. 1 to 7 in the 180-degree peel test were measured by the methods described hereinabove.

### (Coefficient of Linear Expansion)

The coefficient of linear expansion is the coefficient of thermal expansion of the dielectric sheet in the thickness direction. Dielectric sheets No. 1 to 7 were first cut, and the coefficient of linear expansion was calculated from found values from 20° C. to 120° C. by a measurement system using laser interferometry (thermal expansion measurement system by laser interferometer LIX-2, manufactured by ADVANCE RIKO, Inc.). As a result, the coefficient of linear expansion was found to be 30 ppm/° C. A dielectric sheet was manufactured in the same manner as for No. 1 to 7, except that the amount of silica fillers was 100 parts by mass per 100 pars by mass of the polytetrafluoroethylene, and that the number of times of the process of folding in a zigzag manner was zero, and the coefficient of thermal expansion of this sheet was 54 ppm/° C. Another dielectric sheet was manufactured in the same manner as for No. 1 to 7, except that the amount of silica fillers was 130 parts by mass per 100 pars by mass of the polytetrafluoroethylene, and the coefficient of thermal expansion of this sheet was 45 ppm/° C. It is considered that a coefficient of linear expansion within a range from 10 ppm/° C. to 50 ppm/° C. is favorable.

### (Workability)

As a measure of the workability, the length of burrs of copper foil was measured in the following procedure.

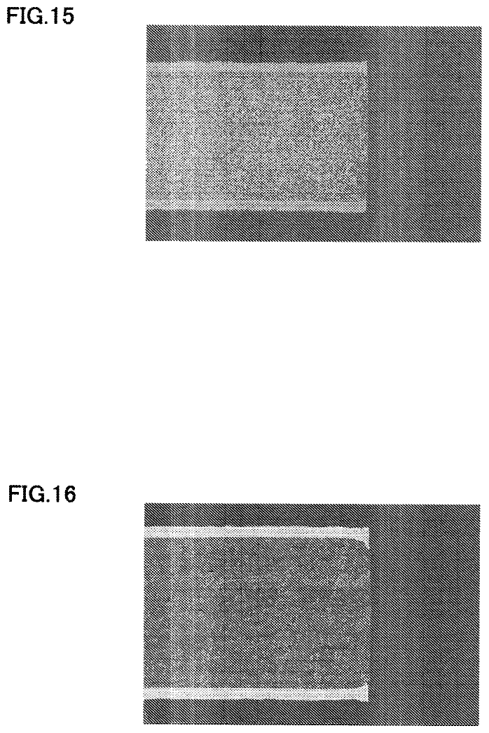

The dielectric sheet was sandwiched between two sheets of copper foil each having a thickness of 18 μm via respective adhesive layers made of perfluoroalkoxyalkane and having a thickness of 1 μm, and 3000 through holes were made using a drill for laminate. The cross section of the 3000th hole was observed under a SEM, and the burrs generated in the copper foils were measured. FIG. 15 is a SEM image showing burrs generated in the copper foils of No. 5, and FIG. 16 is a SEM image showing burrs generated in the copper foils of No. 7.

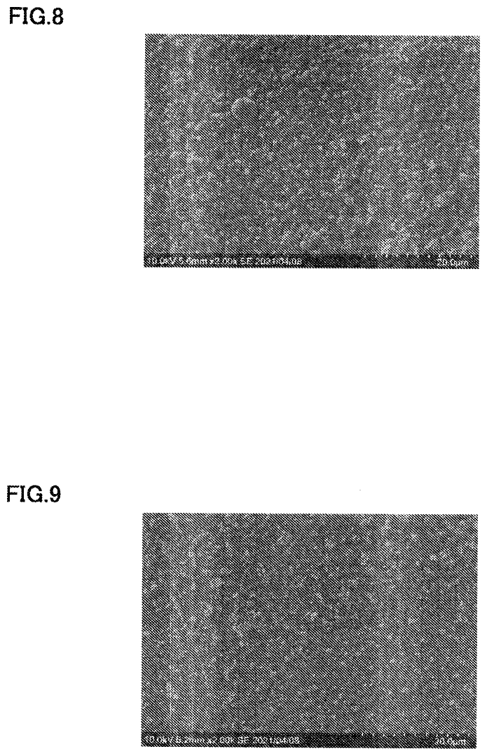

Evaluation results of dielectric sheets No. 1 to No. 7 are shown in Table 1. The sign “-” indicates that the corresponding component is not included. FIGS. 8 to 14 show SEM (“FLEXSEM1000” manufactured by Hitachi High-Tech Corporation.) images of the surfaces of dielectric sheets No. 1 to No. 7 after the 180-degree peel test. In these images, the substances that appear in the form of lines are fibrous bodies of the polytetrafluoroethylene, and the substances that appear in the form of spheres are silica fillers.

### [Table 1]

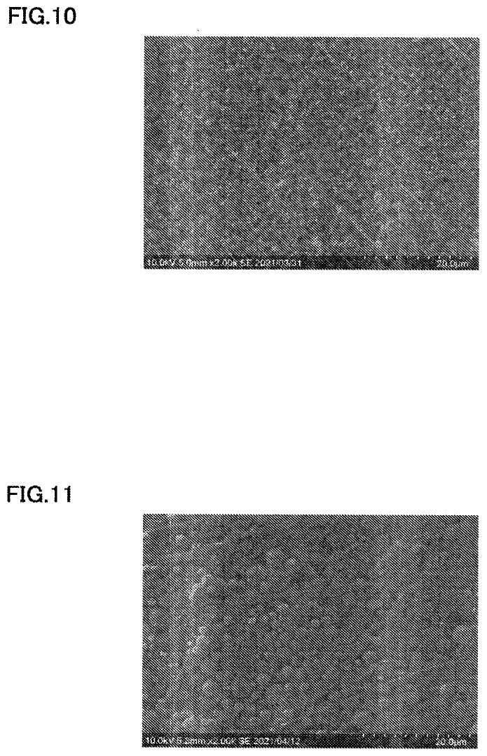

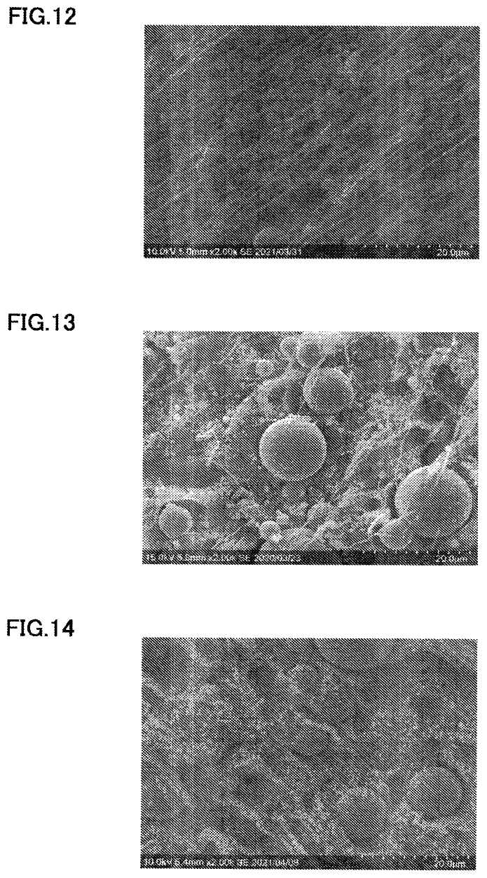

TABLE 1

| Test Example No. | | | 1 | 2 | 3 | 4 | 5 | 6 | 7 |
|---|---|---|---|---|---|---|---|---|---|
| Material | Mass of PTFE (parts by | | 100 | 100 | 100 | 100 | 100 | 100 | 100 |
| | mass) | | | | | | | | |
| | Silica | Mass of silica filler | 175.0 | 175.0 | 175.0 | 175.0 | 175.0 | 175.0 | 175.0 |
| | filler | (parts by mass) | | | | | | | |
| | | Average particle | 0.5 | 0.5 | 0.5 | 2.0 | 2.0 | 7.0 | 7.0 |
| | | diameter of silica | | | | | | | |
| | | filler [μm] | | | | | | | |
| | Titanium | Mass of titanium | 5.0 | 5.0 | 5.0 | 5.0 | 5.0 | 5.0 | 5.0 |
| | oxide | oxide (parts by | | | | | | | |
| | | mass) | | | | | | | |
| | | Average particle | 0.2 | 0.2 | 0.2 | 0.2 | 0.2 | 0.2 | 0.2 |
| | | diameter of titanium | | | | | | | |
| | | oxide [μm] | | | | | | | |

| | | | | | | | | |
|---|---|---|---|---|---|---|---|---|
| | Mass ratio of total silica filler | 1.750 | 1.750 | 1.750 | 1.750 | 1.750 | 1.750 | 1.750 |
| | to PTFE | | | | | | | |
| | Mass of auxiliary (parts by | 47 | 47 | 47 | 47 | 47 | 47 | 47 |
| | mass) | | | | | | | |
| Evaluations | Peel strength in 180-degree | 2 | 5 | 11 | 7 | 12 | 8 | 14 |
| | peel test [N/cm] | | | | | | | |
| | Fibrous bodies with thickness | No | Yes | Yes | Yes | Yes | No | No |
| | of 0.1 μm or more and 3.0 μm | | (small | | (small | | | |
| | or less and length of 50 μm or | | number) | | number) | | | |
| | more and 5000 μm or less | | | | | | | |
| | after 180-degree peel test | | | | | | | |
| | Average space between the | — | more | 10 μm | more | 10 μm | — | — |
| | areas of the at least part of | | than 10 | or less | than 10 | or less | | |
| | fibrous bodies after peel test | | μm | | μm | | | |
| | [μm] | | | | | | | |
| | Coefficient of linear expansion | 30 | 30 | 30 | 30 | 30 | 30 | 30 |
| | [ppm/° C.] | | | | | | | |
| | Workability | 2 | 2 | 2 | 2 | 2 | 10 | 10 |
| | Burr in copper foil [μm] | | | | | | | |
| | Photograph in observation | FIG. 8 | FIG. 9 | FIG. 10 | FIG. 11 | FIG. 12 | FIG. 13 | FIG. 14 |
| | under SEM | | | | | | | |

Dielectric sheets No. 3 to No. 5 each had a mass ratio of the inorganic fillers to the polytetrafluoroethylene of 1.3 or more and an average particle diameter of the inorganic fillers of 0.3 μm or more and 4.0 μm or less, the inorganic fillers including a silica filler, and in the SEM image of the surface after the 180-degree peel test, the average space between the areas of the fibrous bodies was 10 μm or less, the area having a thickness of 0.1 μm or more and 3.0 μm or less and a length of 50 μm or more and 5000 μm or less. From the results in Table 1, such dielectric sheets No. 3 to No. 5 each had a large peel strength in the 180-degree peel test, and favorable workability and coefficient of linear expansion. On the other hand, in the SEM image of the surface after the peel test of dielectric sheets No. 2 and No. 4 at 180 degrees, the average space between the areas of the fibrous bodies was more than 10 μm, the areas having a thickness of 0.1 μm or more and 3.0 μm or less and a length of 50 μm or more and 5000 μm or less. Such dielectric sheets No. 2 and No. 4 each had a small peel strength in the 180-degree peel test.

In each of the SEM images of the surfaces after the peel test of dielectric sheets No. 1, No. 6, and No. 7 at 180 degrees, it was found that no fibrous bodies having areas with a thickness of 0.1 μm or more and 3.0 μm or less and a length of 50 μm or more and 5000 μm or less were formed, and accordingly, it was impossible to measure the average space between the areas of the at least part of the fibrous bodies.

It was shown from the above results that the dielectric sheet is excellent in characteristics in high frequencies, workability, and peel strength.

### REFERENCE SIGNS LIST

1 Sheet body; 2 Divided body; 3 Divided body; 4 Divided body; 5 Divided body; 6 Peeling vector; 7a, 7b, 7c Approximate line segment; L1, L2 Distance; 8 Fibrous body; 9 Arrow; 10 Laminate; 60 Copper foil; 70 Dielectric sheet; 100 Substrate for a high frequency printed wiring board

1. A dielectric sheet comprising a polytetrafluoroethylene and spherical inorganic fillers, wherein
a mass ratio of the inorganic fillers to the polytetrafluoroethylene is 1.3 or more,
the inorganic fillers have an average particle diameter of 0.3 μm or more and 4.0 μm or less,
the inorganic fillers comprise a silica filler,
part of the polytetrafluoroethylene is present in the form of a plurality of fibrous bodies, and
in a SEM image of a surface of the dielectric sheet after a 180-degree peel test, at least part of fibrous bodies among the plurality of fibrous bodies has areas with a thickness of 0.1 μm or more and 3.0 μm or less and a length of 50 μm or more and 5000 μm or less, and an average space between the areas of the at least part of fibrous bodies is 10 μm or less.

2. The dielectric sheet according to claim 1, wherein a peel strength in the 180-degree peel test is 10 N/cm or more.

3. The dielectric sheet according to claim 1, wherein a content of the silica filler in the inorganic fillers is 70 mass % or more and 100 mass % or less.

4. The dielectric sheet according to claim 1, wherein the silica filler has, on a surface thereof, a hydrocarbon group having 4 or more carbon atoms.

5. A substrate for a high frequency printed wiring board, comprising
the dielectric sheet according to claim 1, and
copper foil directly or indirectly laid on a surface of the dielectric sheet.

6. A high frequency printed wiring board comprising the substrate for a high frequency printed wiring board according to claim 5.
